(19) United States
(12) Patent Application Publication
(10) Pub. No.: US 2025/0185194 A1
(43) Pub. Date: Jun. 5, 2025

(54) SEALED ELECTRONICS ENCLOSURES AND METHODS OF MANUFACTURING

(71) Applicant: Covidien LP, Mansfield, MA (US)

(72) Inventors: Stacy L. WILLETT, Lafayette, CO (US); James R. FAGAN, Lafayette, CO (US)

(73) Assignee: Covidien LP, Mansfield, MA (US)

(21) Appl. No.: 18/842,722

(22) PCT Filed: Feb. 14, 2023
(86) PCT No.: PCT/IB2023/051327

§ 371 Date: Aug. 29, 2024

Related U.S. Application Data
(60) Provisional application No. 63/315,774, filed on Mar. 2, 2022.

(51) Int. Cl. H05K 5/02; H05K 5/00

(52) U.S. Cl. CPC H05K 5/023; H05K 5/0086

(57) ABSTRACT

An electronics enclosure includes first and second enclosure components sealingly joined to one another along a seam thereby defining a stress location. A coating is disposed at the stress location to inhibit chemical interactions with the stress location, thereby maintaining the integrity of the seam. Another electronics enclosure includes at least one sealed enclosure component including a feature that defines a stress location on the at least one sealed enclosure component. A coating is disposed at the stress location to inhibit chemical interactions with the stress location, thereby maintaining the integrity of the at least one sealed enclosure component.

### FIELD

The present disclosure relates to sealed electronics enclosures and methods of manufacturing the same. More specifically, the present disclosure relates to sealed electronics enclosures, e.g., such as for use in surgical instruments, and methods of manufacturing the same that maintain or improve the integrity of the sealed enclosure, e.g., inhibiting fluid and/or debris ingress.

### BACKGROUND

Sealed electronics enclosures are utilized to inhibit debris and fluid ingress to internal electronics, e.g., batteries, control circuitry, generator circuitry, communication circuitry, motors, transducers, sensors, etc., in a wide variety of fields ranging from consumer electronics to surgical instruments.

With respect to surgical instruments, for example, untethered surgical instruments are advantageous in that they obviate the need for cables coupling the instrument to external inputs by incorporating these input components onto and/or into the instrument itself. Accordingly, a number of surgical instrument manufacturers have developed untethered and/or partially untethered energy-based surgical instruments, powered surgical instruments, and the like. In many instances, the electronics, e.g., batteries, controllers, motors, generators, transducers, combinations thereof, etc., of such untethered and/or partially untethered energy-based surgical instruments are enclosed in one or more sealed electronics enclosures to protect these electronics and inhibit fluid and/or debris ingress, e.g., during use or during cleaning, disinfection, and/or sterilization in preparation for further use.

### SUMMARY

The terms “about,” “substantially,” and the like, as utilized herein, are meant to account for manufacturing, material, environmental, use, and/or measurement tolerances and variations, and in any event may encompass differences of up to 10%. Further, to the extent consistent, any of the aspects described herein may be used in conjunction with any or all of the other aspects described herein.

Provided in accordance with aspects of the present disclosure is an electronics enclosure including first and second enclosure components sealingly joined to one another along a seam such that a stress location is defined. A coating is disposed at the stress location to inhibit chemical interactions with the stress location (such as, for example, chemical interactions as a result of cleaning and/or disinfecting agents coming into contact with the stress location), thereby maintaining or improving the integrity of the seam.

In an aspect of the present disclosure, the first and second enclosure component are ultrasonically welded to one another along the seam.

In another aspect of the present disclosure, the first and second enclosure components are formed from ABS or other suitable polymers.

In aspects of the present disclosure, the coating is a glue or adhesive, an elastomeric coating, a hydrophobic coating, and/or a plastic.

In still another aspect of the present disclosure, at least one battery cell is sealing enclosed within the first and second enclosure components.

Another electronics enclosure provided in accordance with the present disclosure includes at least one sealed enclosure component including a feature that defines a stress location on the at least one sealed enclosure component. A coating is disposed at the stress location to inhibit chemical interactions with the stress location (such as, for example, chemical interactions as a result of cleaning and/or disinfecting agents coming into contact with the stress location), thereby maintaining or improving the integrity of the at least one sealed enclosure component.

In an aspect of the present disclosure, the at least one sealed enclosure component includes first and second sealed enclosure components and the feature is a seam defined between the first and second sealed enclosure components.

In still another aspect of the present disclosure, the at least one sealed enclosure component includes first and second sealed enclosure components joined at an angle relative to one another at a joint, and the feature is the joint.

In yet another aspect of the present disclosure, at least one sealed enclosure component includes first and second portions of different thickness, and the feature is a transition between the first and second portions.

In still yet another aspect of the present disclosure, the at least one sealed enclosure is molded and the feature is at least one of: a knit line of the at least one molded sealed enclosure component or a gate of the at least one molded sealed enclosure component.

In another aspect of the present disclosure, the feature is a snap-fit connector of the at least one sealed enclosure component or a boss of the at least one sealed enclosure component.

In another aspect of the present disclosure, the at least one enclosure component is formed from ABS or other suitable polymers.

In aspects of the present disclosure, the coating is a glue or adhesive, an elastomeric coating, a hydrophobic coating, and/or a plastic.

### BRIEF DESCRIPTION OF THE DRAWINGS

Various aspects and features of the present disclosure are described hereinbelow with reference to the drawings wherein:

FIG. 1 is a perspective view of a surgical instrument provided in accordance with aspects of the present disclosure;

FIG. 2 is a side view of the surgical instrument of FIG. 1 with a generator and transducer assembly removed from a body of the surgical instrument and illustrating removal of a battery assembly from the body of the surgical instrument;

FIG. 3 is a perspective view of a portion of the battery assembly of the surgical instrument of FIG. 1;

FIG. 4 is an enlarged, perspective view of the area of detail indicated as “4” in FIG. 3;

FIG. 5 is a cross-sectional view of a completed ultrasonic weld joint of an electronics enclosure;

FIGS. 6A and 6B are cross-sectional views of bosses formed in electronics enclosures;

FIGS. 7A and 7B are perspective view of material junctions formed in electronics enclosures;

FIG. 8 is a greatly enlarged, cross-sectional view illustrating a knit line in an electronics enclosure;

FIG. 9 is a greatly enlarged, cross-sectional view illustrating a gate location of an electronics enclosure;

FIG. 10 is a perspective view of a snap-fit connector of an electronics enclosure;

FIG. 11A is a cross-sectional view illustrating first and second components and a seal prior to ultrasonic welding of the first and second components with one another;

FIG. 11B is a cross-sectional view illustrating the first and second components of FIG. 11A ultrasonically welded with the seal of FIG. 11A captured therebetween and disposed along an external seam thereof;

FIG. 11C is a cross-sectional view illustrating first and second components and another seal prior to ultrasonic welding of the first and second components with one another;

FIG. 11D is a cross-sectional view illustrating the first and second components of FIG. 11C ultrasonically welded with the seal of FIG. 11C captured therebetween and disposed within an ultrasonic weld reveal formed between the first and second components; and

FIG. 11E is a cross-sectional view illustrating first and second components ultrasonically welded with a glue or adhesive disposed within an ultrasonic weld reveal formed between the first and second components.

### DETAILED DESCRIPTION

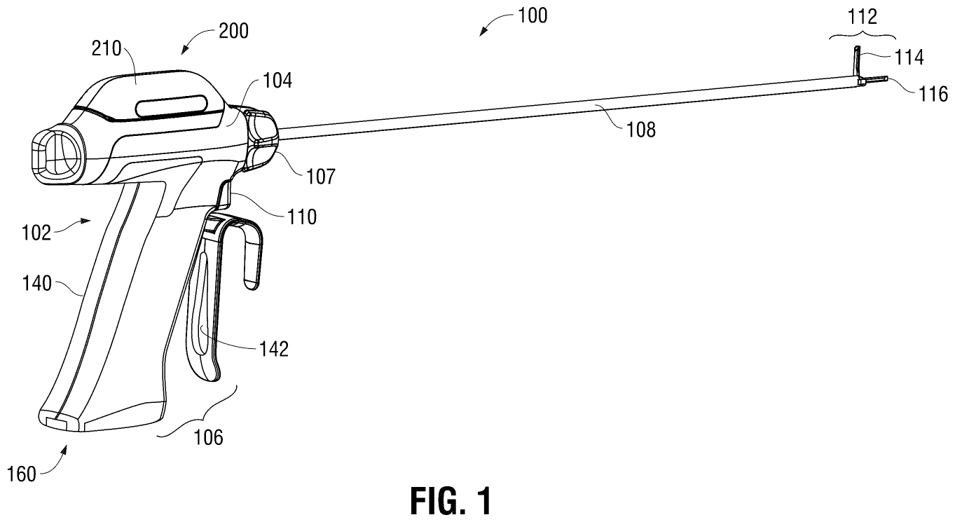

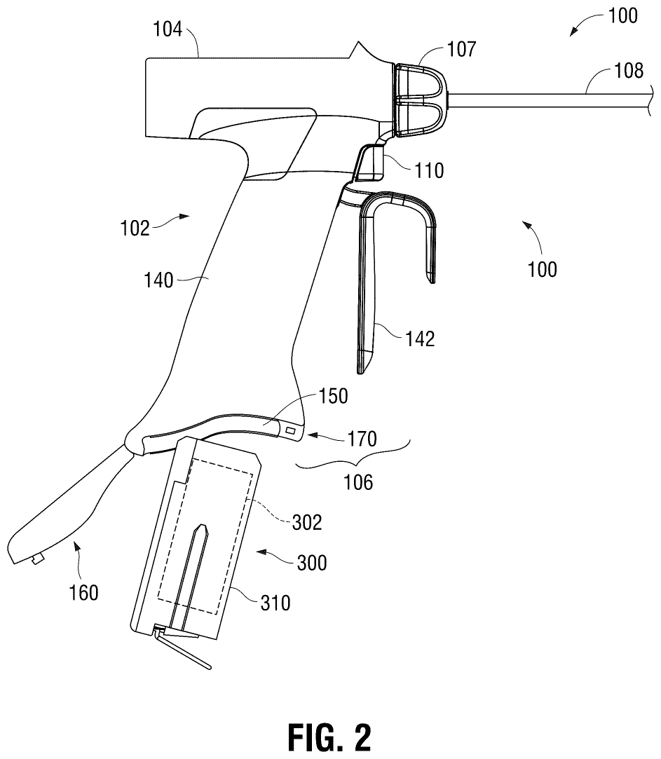

Referring to FIGS. 1 and 2, an ultrasonic surgical instrument 100 provided in accordance with the aspects and features of the present disclosure is shown configured to releasably mount a transducer and generator assembly (“TAG”) 200 thereon and to releasably enclose a battery assembly 300 within a battery compartment 150 thereof. Electronics 302 associated with battery assembly 300, e.g., one or more battery cells, control circuitry, monitoring circuitry, etc., and/or electronics associated with TAG 200, e.g., generator circuitry, control circuitry, monitoring circuitry, etc., may be enclosed within one or more sealed electronics enclosures such as, for example, enclosure 310 of battery assembly 300 and/or enclosure 210 of TAG 200, respectively. Although described hereinbelow with respect to enclosure 310 of battery assembly 300, the aspects and features of the present disclosure are equally applicable to any other suitable sealed electronics enclosures. For the purposes herein, ultrasonic surgical instrument 100 is generally described.

Continuing with reference to FIGS. 1 and 2, ultrasonic surgical instrument 100 generally includes a body 102 including a housing 104, a handle assembly 106, a rotating assembly 107, a shaft 108, an activation button 110, and an end effector assembly 112. Battery assembly 300 is releasably insertable into battery compartment 150 defined within handle assembly 106 of body 102. TAG 200 is releasably mountable on housing 104 of body 102. However, it is also contemplated that, rather than mounting on housing 104, TAG 200 be configured for releasably insertion into a TAG compartment defined within housing 104, similarly as with respect to the releasable insertion of battery assembly 300 into battery compartment 150. Handle assembly 106 further includes a door 160 having a lock assembly 170 associated therewith for releasably locking door 160 to secure battery assembly 300 within battery compartment 150.

Shaft 108 of ultrasonic surgical instrument 100 is coupled to housing 104 at a proximal end of shaft 108 and extends distally from housing 104. End effector assembly 112 is disposed at a distal end of shaft 108 and includes first and second jaw members 114, 116, one or both of which is movable relative to the other, e.g., upon actuation of movable handle 142 of handle assembly 106, between an open position and a clamping position for grasping tissue therebetween. One of the jaw members, e.g., jaw member 116, is configured to serve as an active or oscillating ultrasonic blade that is selectively activatable to ultrasonically treat tissue grasped between jaw members 114, 116. More specifically, TAG 200 is configured to convert electrical energy provided by battery assembly 300 into mechanical energy that produces motion at the end of a waveguide that extends from the ultrasonic transducer of TAG 200 through shaft 108 and terminates at jaw member 116. The electronics of TAG 200 (e.g., disposed within sealed TAG enclosure 210), convert the electrical energy provided by battery assembly 300 into a high voltage AC waveform that drives the transducer of TAG 200 to thereby produce mechanical motion, e.g., ultrasonic motion, that is transmitted along the waveguide to active jaw member 116 for treating tissue grasped between jaw members 114, 116 or otherwise in close proximity with active jaw member 116. Activation button 110 is disposed on housing 104 and is selectively activatable in one or more activated positions to supply electrical energy from battery assembly 300 to TAG 200 for operating ultrasonic surgical instrument 100 in at least one mode, e.g., a low-power mode of operation and a high-power mode of operation.

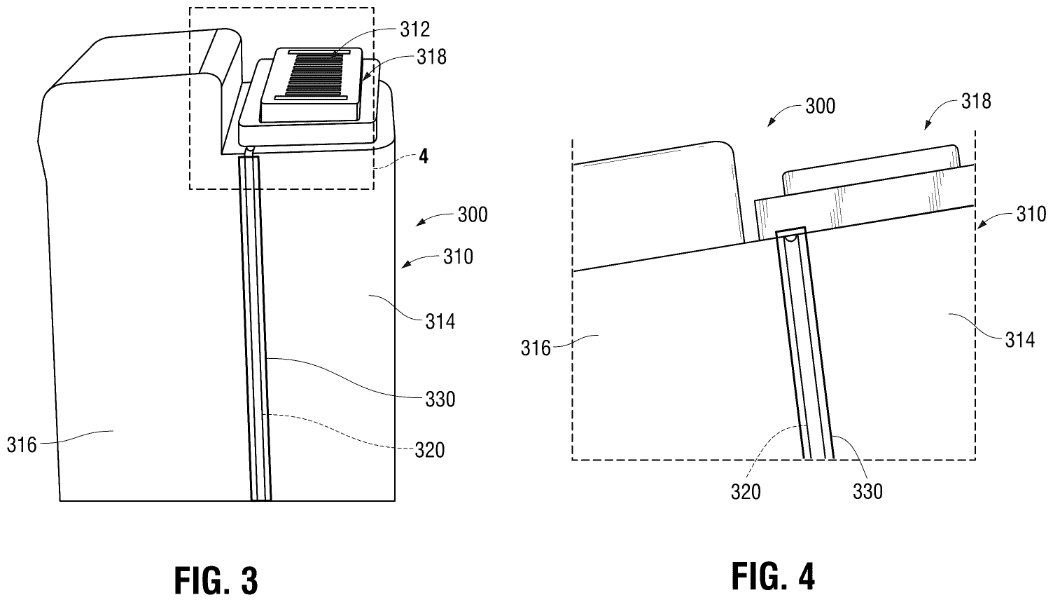

Handle assembly 106 includes a fixed handle 140 that is integral with housing 104 and movable handle 142 which is operably coupled to end effector 112 and movable relative to fixed handle 140 between a spaced-apart position and a compressed position to move jaw members 114, 116 between the open position and the clamping position. Fixed handle 140 includes a hollow interior portion so as to define battery compartment 150 therein, and an open free end to enable insertion and removal of battery assembly 300 into battery compartment 150. Fixed handle 140 supports internal contacts (not shown) within battery compartment 150 of handle assembly 106 that are configured to mate with corresponding contacts 312 (FIGS. 3 and 4) of battery assembly 300 upon insertion of battery assembly 300 into battery compartment 150. As such, power and/or control signals can be relayed between battery assembly 300 and TAG 200, which likewise includes contacts (not shown) configured to mate with corresponding internal contacts (not shown) of housing 104 of body 102 upon engagement of TAG 200 therewith.

Referring to FIGS. 3 and 4, as noted above, the internal electronics 302 associated with battery assembly 300, e.g., one or more battery cells, control circuitry, monitoring circuitry, etc., are enclosed within sealed electronics enclosure 310. Sealed electronics enclosure 310 may be formed about the internal electronics 302 via ultrasonically welding first and second enclosure parts 314, 316 to one another thereby securing a connector body 318 that contains contacts 312 therebetween. Enclosure parts 314, 316 may be formed from acrylonitrile butadiene styrene (ABS) or other suitable polymers. However, it is also contemplated that sealed electronics enclosure 310 be formed from more than two enclosure parts 314, 316, that connector cap 318 be omitted and/or additional connector components be provided, that sealed electronics enclosure 310 is formed from methods other than ultrasonic welding, and/or that sealed electronics enclosure 310 is formed from different material(s).

Regardless of the component and/or manner of formation of enclosure 310, stress locations may be created as a result of the manufacturing of components, joining of components, features of the components, and/or loading of the components of enclosure 310. For example, with respect to ultrasonic welding, a seam 320 may be formed at the interface where the two enclosure parts 314, 316 were joined. Seam 320 is a stress location in that, while seam 320 is sufficiently sealed to inhibit fluid and/or debris ingress, at least initially, seam 320 defines a decreased thickness as compared to other portions of enclosure 310 and/or the ultrasonic welding process has stressed seam 320 such that seam 320 may be particularly susceptible to damage, e.g., cracking, softening, swelling, erosion, etc., from physical interactions (stresses, friction, contact with other components, etc.) and/or chemical interactions (such as, for example, from disinfectant and other chemicals and/or fluids, e.g., of cleaning wipes used to wipe down and/or clean enclosure 310 between uses). Chemicals that may be encountered and cause the above-noted chemical interactions, e.g., chemicals of common disinfectant wipes, include, but are not limited to: isopropanol, ethyl alcohol, dodecyl dimethyl ammonium chloride, and quarternary ammonium.

While the above-noted chemical and physical interactions may not be sufficient to compromise all portions of enclosure 310 throughout its useful life, such interactions at stress locations, e.g., seam 320, may result in damage, e.g., cracking, softening, swelling, erosion, etc., that compromises the fluid-sealed enclosure 310 within is useful life, potentially leading to fluid and/or debris ingress into the interior of enclosure 310 which may damage the internal electronics and/or present performance and/or safety issues. Stress locations are not limited to seams, e.g., seam 320; rather, various other stress locations typically found in sealed electronics enclosures are detailed below (without limitation to only these stress locations).

In order to inhibit chemical interactions at stress locations, e.g., seam 320, enclosure 310 includes a coating 330 covering at least seam 320 (in aspects, only seam 320 and/or other stress locations; in other aspects, coating 330 may cover the entirety of enclosure 310 or various portions thereof). Coating 330 need not significantly increase the structural support at seam 320 and/or compensate for the increased stresses at seam 320. Rather, coating 330 is provided to inhibit chemicals from contacting seam 320, thereby inhibiting the above-noted chemical interactions (and, in aspects, also at least some of the above-noted physical interactions) such that damage, e.g., cracking, softening, swelling, erosion, etc., at seam 320 is inhibited and the integrity of the fluid-tight seal along seam 320 is maintained for the useful life of enclosure 310. That is, coating 330 may allow enclosure 310 to be formed from a material(s) with better strength and/or impact resistance but which may exhibit poor resistance to chemicals (particularly at stress locations). Further, coating 330 need not be limited to an external coating as internal coatings and/or intermediate coatings (between components) are also contemplated.

Coating 330 applied over stress locations (and/or other locations on or within enclosure 310) are, in aspects, free of the stresses of the underlying stress locations and may include, for example, glues/adhesives, conformal coatings, deposition coatings, dip coatings, hydrophobic coatings, any/or other suitable coatings. Specific coatings include, but are not limited to: perylene, acrylic (including UV or other light-curable acrylic adhesives), silicone, polyurethane, hexamethyldisiloxane (HMDSO), ethylene tetrafluoroethylene, perfluoroalkoxy alkane, fluorinated high-density polyethylene, high-density polyethylene, low-density polyethylene, polypropylene, fluorinated polypropylene, polycarbonate, glycolized polyester, polyvinyl chloride, cynaacrolate, and thermoplastic elastomer (or other elastomeric coating). Coating 330 may be applied in any suitable manner.

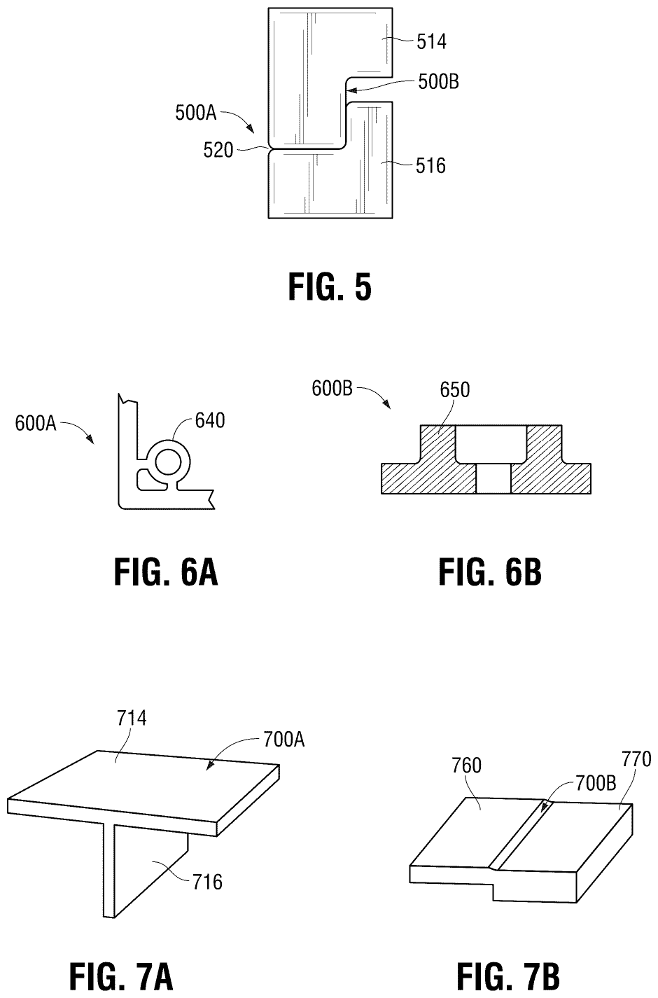

Turning to FIGS. 5-10, various stress locations created as a result of the manufacturing of components, joining of components, features of the components, and/or loading of components are illustrated, although stress locations may be formed in other manners. FIG. 5 illustrates a stress location 500A defined in an enclosure at an external seam 520 of an ultrasonic weld between first and second enclosure components 514, 516, respectively, similarly as with seam 320 of enclosure 310 (FIGS. 3 and 4), and/or a stress location 500B defined in a thinned portion of first enclosure component 514 as a result of the ultrasonic weld reveal required for ultrasonic welding (to form the seam).

FIGS. 6A and 6B illustrate bosses 640, 650, respectively, of an enclosure, e.g., for retaining pins, screws, and/or other components, of enclosure that, as a result of their construction and/or stresses imparted thereto by the components retained thereby, define stress locations 600A, 600B of the enclosure.

An enclosure wherein two different sections of material 714, 716 are joined at an angle relative to one another, e.g., at a joint, may define a stress location 700A, as shown in FIG. 7A, and/or a stress location 700B may be defined, as shown in FIG. 7B, along a transition between a relatively thinner portion 760 of an enclosure and a relatively thicker portion 770 of the enclosure. The enclosures components 714, 716 and 760, 770 of FIGS. 7A and 7B, respectively, (or any of the other enclosure or enclosure components in accordance with the present disclosure) may be formed via injection molding, overmolding, or other suitable molding process and, thus, molding stresses (temperature, pressure, etc.) may contribute to the formation of stress locations 700A, 700B.

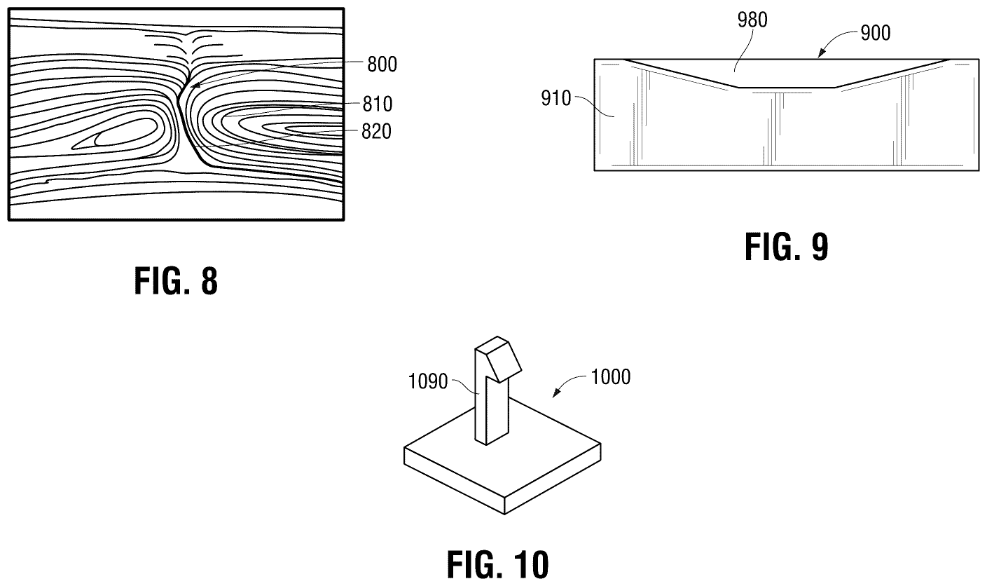

As illustrated in FIG. 8 a knit line 820 formed as a result of the molding process, e.g., to form an enclosure component 810, may define a stress location 800 of the enclosure (by itself or in addition to the above-noted molding stresses). Similarly, with reference to FIG. 9, a stress location 900 may be defined on an enclosure component 910 of an enclosure at a gate defect 980 where a gate was utilized to introduce mold material to form the component 910 of the enclosure during manufacturing.

FIG. 10 illustrates a snap-fit connector 1090 of an enclosure that, by its configuration and/or due to the loading of the snap-fit connector 1090 when engaged with a corresponding snap-fit connector (not shown), defines a stress location 1000 of the enclosure.

Stress locations may additionally be formed in other manners and/or due to other features such as, for example and without limitation, as a result of any other spring loading of a plastic component(s), at or near threaded fasteners, at or near press-fit engagements, at the interface between a plastic component(s) and a component(s) of other material (non-plastic or a different plastic), etc.

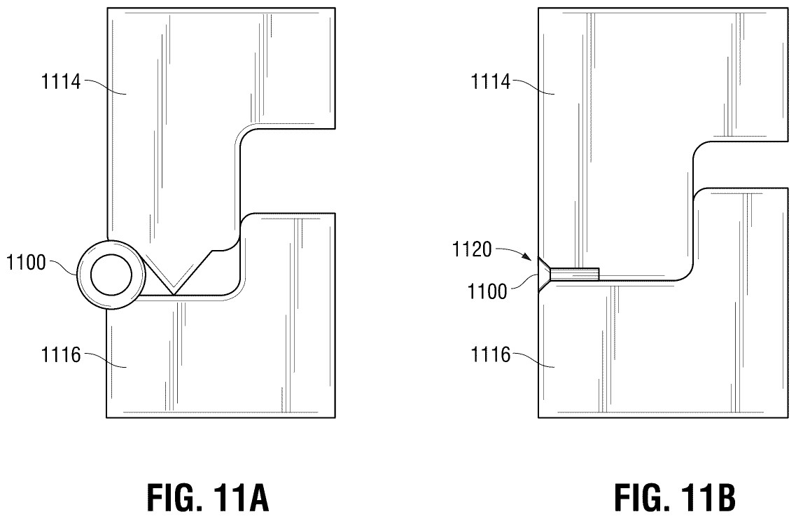

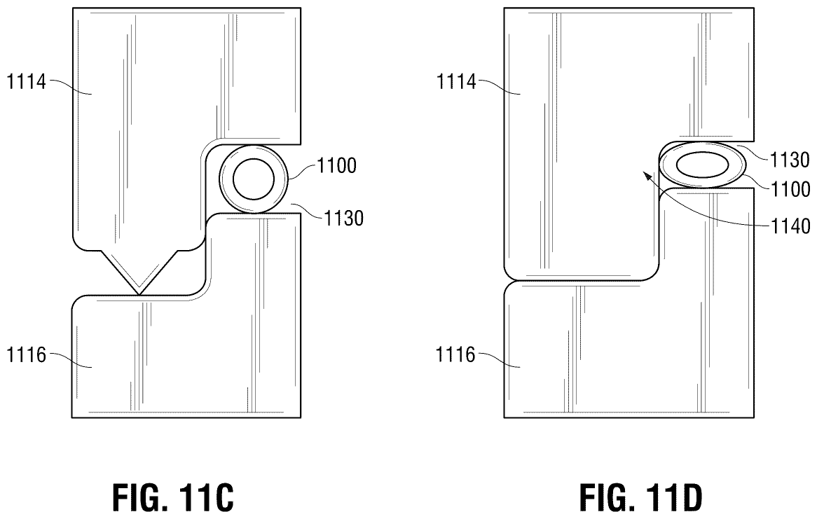

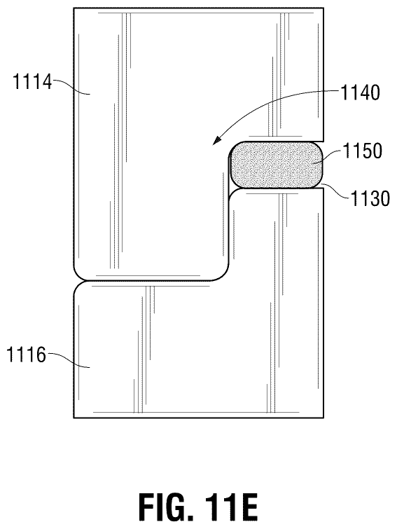

Turning to FIGS. 11A and 11B, as an alternative or in addition to coating the stress locations(s) of an enclosure, a seal 1100 such as, for example, an elastomeric tube, may be positioned along external edges and partially between first and second enclosure components 1114, 1116, respectively, configured to be ultrasonic welded to one another such that, upon ultrasonic welding of the first and second enclosure components 1114, 1116, respectively, with one another, seal 1100 is captured therebetween and substantially seals the external side of the seam 1120 defined between the ultrasonically welded first and second enclosure components 1114, 1116, respectively. In other aspects, seal 1100 may be positioned over seam 1120, on the external side thereof, after ultrasonic welding is complete.

Referring to FIGS. 11C and 11D, alternatively or additionally, seal 1100 may be positioned within an internal ultrasonic weld reveal 1130 defined between first and second enclosure components 1114, 1116 such that, upon ultrasonic welding of first and second enclosure components 1114, 1116 to one another, the weld reveal 1130 partially collapses to thereby capture seal 1100 between first and second enclosure components 1114, 1116 and substantially seal the weld reveal 1130. Such a configuration maintains and/or improves the fluid and/or debris ingress protection at seam 1120 (FIG. 11B), the thinned portion 1140 of first enclosure component 1114, and/or other stress locations.

With reference to FIG. 11E, as an alternative or in addition to a seal 1100 (FIG. 11D), a coating 1150, e.g., a glue or adhesive, may be positioned within the internal ultrasonic weld reveal 1130 defined between first and second enclosure components 1114, 1116 (prior to ultrasonic welding) to substantially seal the weld reveal 1130 (after ultrasonic welding). Similarly as above, such a configuration maintains and/or improves the fluid and/or debris ingress protection at seam 1120 (FIG. 11B), the thinned portion 1140 of first enclosure component 1114, and/or other stress locations.

It will be understood that various modifications may be made to the aspects and features disclosed herein. Therefore, the above description should not be construed as limiting, but merely as exemplifications of various aspects and features. Those skilled in the art will envision other modifications within the scope and spirit of the claims appended thereto.

What is claimed is:

1. An electronics enclosure, comprising:
a first enclosure component;
a second enclosure component, wherein the first and second enclosure components are sealingly joined to one another along a seam, thereby defining a stress location; and
a coating disposed at the stress location to inhibit chemical interactions with the stress location, thereby maintaining or improving the integrity of the seam.

2. The electronics enclosure according to claim 1, wherein the first and second enclosure component are ultrasonically welded to one another along the seam.

3. The electronics enclosure according to claim 1, wherein the first and second enclosure components are formed from ABS.

4. The electronics enclosure according to claim 1, wherein the coating is a glue or an adhesive.

5. The electronics enclosure according to claim 1, wherein the coating is an elastomeric coating.

6. The electronics enclosure according to claim 1, wherein the coating is a hydrophobic coating.

7. The electronics enclosure according to claim 1, wherein the coating is a plastic.

8. The electronics enclosure according to claim 1, further comprising at least one battery cell sealing enclosed within the first and second enclosure components.

9. An electronics enclosure, comprising:
at least one sealed enclosure component including a feature that defines a stress location on the at least one sealed enclosure component; and
a coating disposed at the stress location to inhibit chemical interactions with the stress location, thereby maintaining or improving the integrity of the at least one sealed enclosure component.

10. The electronics enclosure according to claim 9, wherein the at least one sealed enclosure component includes first and second sealed enclosure components and wherein the feature is a seam defined between the first and second sealed enclosure components.

11. The electronics enclosure according to claim 9, wherein the at least one sealed enclosure component includes first and second sealed enclosure components joined at an angle relative to one another at a joint, and wherein the feature is the joint.

12. The electronics enclosure according to claim 9, wherein the at least one sealed enclosure component includes first and second portions of different thickness, and wherein the feature is a transition between the first and second portions.

13. The electronics enclosure according to claim 9, wherein the at least one sealed enclosure is molded and wherein the feature is at least one of: a knit line of the at least one molded sealed enclosure component or a gate of the at least one molded sealed enclosure component.

14. The electronics enclosure according to claim 9, wherein the feature is a snap-fit connector of the at least one sealed enclosure component.

15. The electronics enclosure according to claim 9, wherein the feature is a boss of the at least one sealed enclosure component.

16. The electronics enclosure according to claim 9, wherein the at least one enclosure component is formed from ABS.

17. The electronics enclosure according to claim 9, wherein the coating is a glue or an adhesive.

18. The electronics enclosure according to claim 9, wherein the coating is an elastomeric coating.

19. The electronics enclosure according to claim 9, wherein the coating is a hydrophobic coating.

20. The electronics enclosure according to claim 9, wherein the coating is a plastic.
